(19) United States
(12) Patent Application Publication
(10) Pub. No.: US 2025/0151626 A1
(43) Pub. Date: May 8, 2025

(54) SENSOR AND GRIPPING LOAD DETECTION DEVICE

(71) Applicant: Murata Manufacturing Co., Ltd., Nagaokakyo-shi (JP)

(72) Inventors: Kenichi MORI, Nagaokakyo-shi (JP); Hiroyuki KUBO, Nagaokakyo-shi (JP)

(21) Appl. No.: 19/003,458

(22) Filed: Dec. 27, 2024

Related U.S. Application Data
(63) Continuation of application No. PCT/JP2023/022323, filed on Jun. 15, 2023.

(30) Foreign Application Priority Data
Jul. 6, 2022 (JP) 2022-109215

(51) Int. Cl. H10N 30/87; G01B 7/16; H10N 30/30; H10N 30/857

(52) U.S. Cl. CPC H10N 30/875; G01B 7/16; H10N 30/302; H10N 30/857

(57) ABSTRACT

A sensor includes a piezoelectric film having a first and second main surfaces facing each other in a first direction, a first electrode on the first main surface, a second electrode on the second main surface, and a wiring portion. The first electrode and the second electrode overlap each other in the first direction and include a first portion overlapping the piezoelectric film and a second portion that does not overlap the piezoelectric film, the first portion and the second portion are arranged in a second direction orthogonal to the first direction, and the wiring portion includes a wiring substrate overlapping the second portion in the first direction and having a third and a fourth main surface, a first conductor on the third main surface and electrically connected to the first electrode, and a second conductor on the fourth main surface and electrically connected to the second electrode.

### CROSS REFERENCE TO RELATED APPLICATIONS

The present application is a continuation of International application No. PCT/JP2023/022323, filed Jun. 15, 2023, which claims priority to Japanese Patent Application No. 2022-109215, filed Jul. 6, 2022, the entire contents of each of which are incorporated herein by reference.

### TECHNICAL FIELD

The present disclosure relates to a sensor and a gripping load detection device including the sensor.

### BACKGROUND ART

As an disclosure related to a conventional sensor, for example, a piezoelectric film sensor described in Patent Document 1 is known. The piezoelectric film sensor described in Patent Document 1 includes a sensor unit, a circuit unit, and a holding member. The sensor unit outputs piezoelectric voltage corresponding to a strain amount of a piezoelectric film from an output conductor pattern. The circuit unit includes an input conductor pattern to which piezoelectric voltage output from the output conductor pattern is input. The holding member holds the sensor unit and the circuit unit in a state where the output conductor pattern and the input conductor pattern are electrically connected.

Patent Document 1: WO 2016/27615 A

### SUMMARY OF THE DISCLOSURE

In the piezoelectric film sensor described in Patent Document 1, there is a demand for reducing a total area of a portion where the output conductor pattern of the sensor unit and the input conductor pattern of the circuit unit are connected as viewed in a normal direction of a main surface of the sensor unit.

In view of the above, an object of the present disclosure is to provide a sensor in which an area of a portion where an output conductor of a sensor unit and an input conductor of a circuit unit are connected as viewed in a normal direction of a main surface of the sensor unit can be made small, and a gripping load detection device including the sensor.

A sensor according to an embodiment of the present disclosure includes: a piezoelectric film having a first main surface and a second main surface facing each other in a first direction; a first electrode on the first main surface; a second electrode on the second main surface; and a wiring portion, wherein the first electrode and the second electrode overlap each other as viewed in the first direction and include a first portion that overlaps the piezoelectric film and a second portion that does not overlap the piezoelectric film, the first portion and the second portion being arranged in a second direction orthogonal to the first direction, and the wiring portion includes: a wiring substrate that is an insulator, the wiring substrate overlapping the second portion as viewed in the first direction and having a third main surface and a fourth main surface facing each other in the first direction; a first conductor on the third main surface and electrically connected to the first electrode; and a second conductor on the fourth main surface and electrically connected to the second electrode.

According to the sensor of the present disclosure, a connection area between an output conductor of a sensor unit and an input conductor of a circuit unit as viewed in a normal direction of a main surface of the sensor unit can be made small.

### BRIEF EXPLANATION OF THE DRAWINGS

FIG. 1 is a plan view of a sensor 100 according to a first embodiment as viewed in a Z− direction.

FIG. 2 is a sectional view of a sensor unit 1 according to the first embodiment as viewed in a Y+ direction.

FIG. 3 is a plan view of a piezoelectric film 11 according to the first embodiment as viewed in the Z− direction.

FIG. 4 is a plan view of the sensor unit 1 according to the first embodiment as viewed in the Z− direction.

FIG. 5 is a plan view of a wiring portion 2 according to the first embodiment as viewed in the Z− direction.

FIG. 6 is a sectional view of the wiring portion 2 according to the first embodiment as viewed in the Y+ direction.

FIG. 7 is a sectional view taken along line A-A of the sensor 100 according to the first embodiment.

FIG. 8 is a plan view of the wiring portion 2 and a second portion P2 according to the first embodiment as viewed in the Z− direction.

FIG. 9 is a plan view of a sensor 1000 according to a comparative example as viewed in the Z− direction.

FIG. 10 is a sectional view taken along line B-B of the sensor 1000 according to the comparative example.

FIG. 11 is a sectional view taken along line C-C of the sensor 1000 according to the comparative example.

FIG. 12 is a perspective view of a gripping load detection device 200 according to the first embodiment.

FIG. 13 is a sectional view taken along line D-D of the gripping load detection device 200 according to the first embodiment.

FIG. 14 is a plan view of the gripping load detection device 200 according to the first embodiment as viewed in the Z− direction.

FIG. 15 is a sectional view taken along line E-E of the gripping load detection device 200 according to the first embodiment.

FIG. 16 is a plan view of a transmissive housing 3, a first grip 4L, a second grip 4R, and a light emitter 5 according to the first embodiment as viewed in the Z− direction.

FIG. 17 is a diagram illustrating a transparent region ATP and a non-transparent region ANTP of the sensor unit 1 according to the first embodiment.

FIG. 18 is a plan view of a sensor 100a according to a first variation as viewed in the Z− direction.

FIG. 19 is a plan view of the sensor unit 1 according to the first variation as viewed in the Z− direction.

FIG. 20 is a perspective view of a gripping load detection device 200a according to the first variation.

FIG. 21 is a diagram illustrating the transparent region ATP and the non-transparent region ANTP of the sensor 100a according to the first variation.

FIG. 22 is a plan view of a sensor 100b according to a second variation as viewed in the Z− direction.

FIG. 23 is a perspective view of a gripping load detection device 200b according to the second variation.

FIG. 24 is a plan view of the gripping load detection device 200b according to the second variation as viewed in the Z− direction.

### DESCRIPTION OF THE PREFERRED EMBODIMENTS

### First Embodiment

### Configuration of Sensor 100

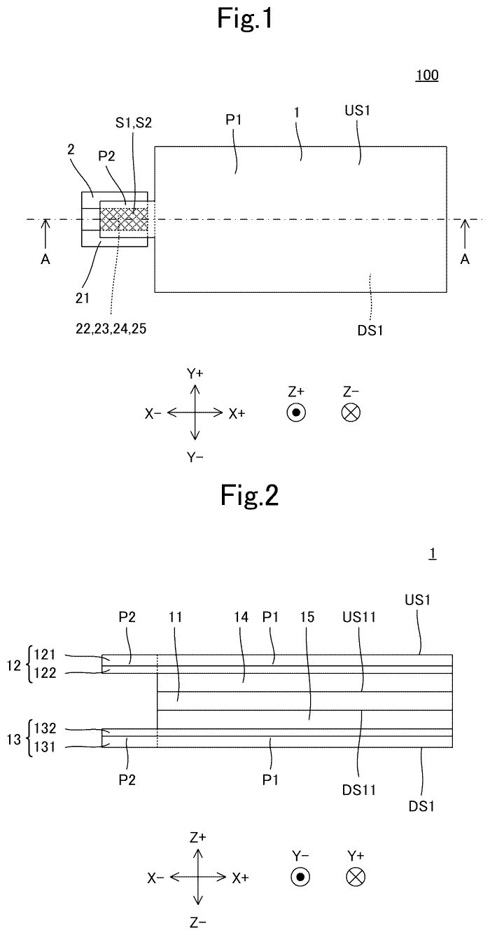

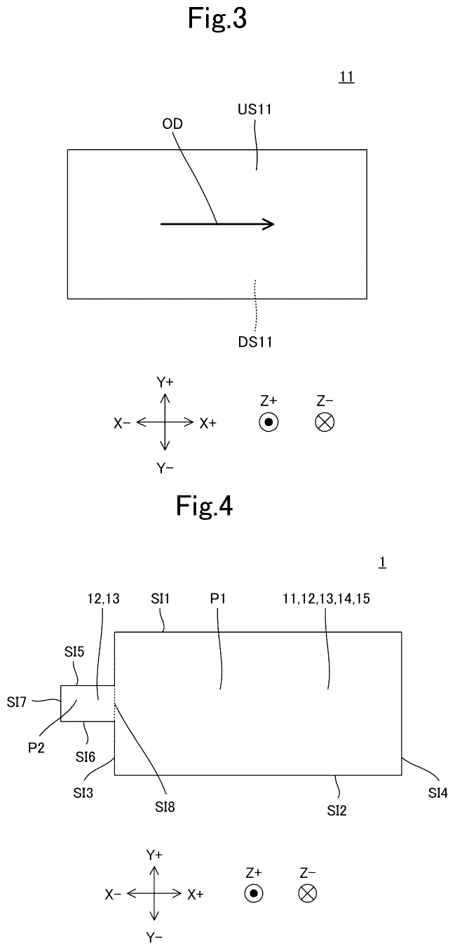

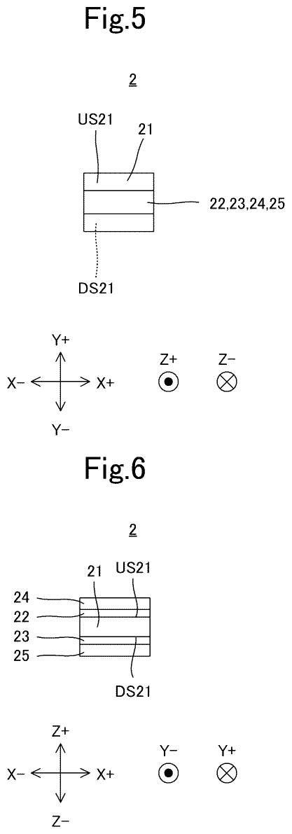

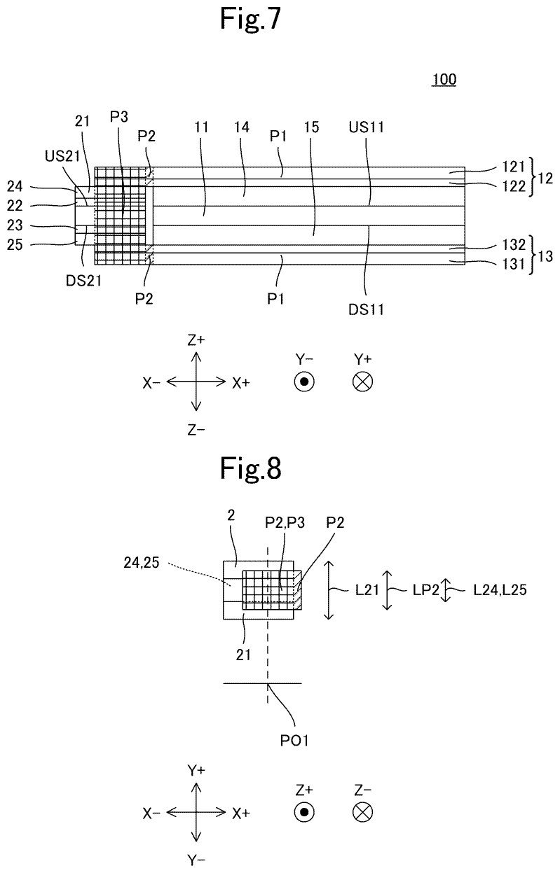

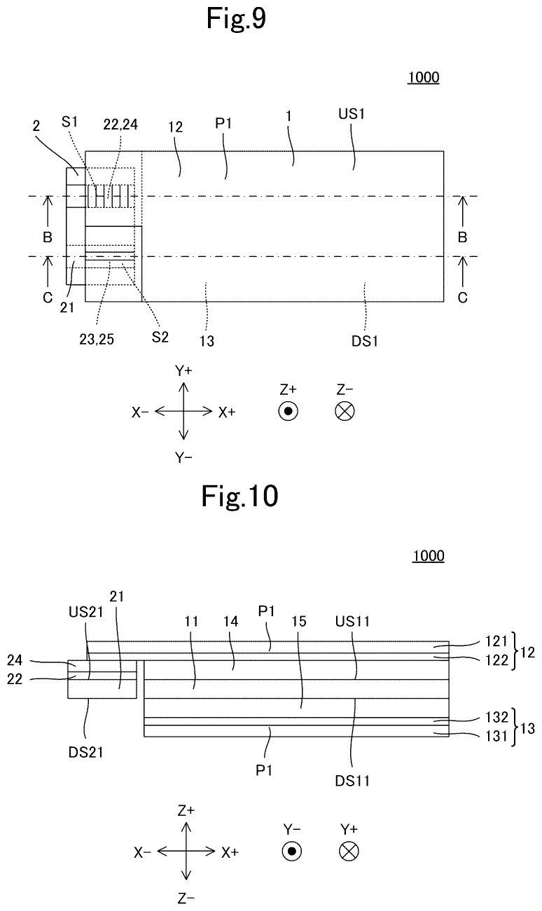

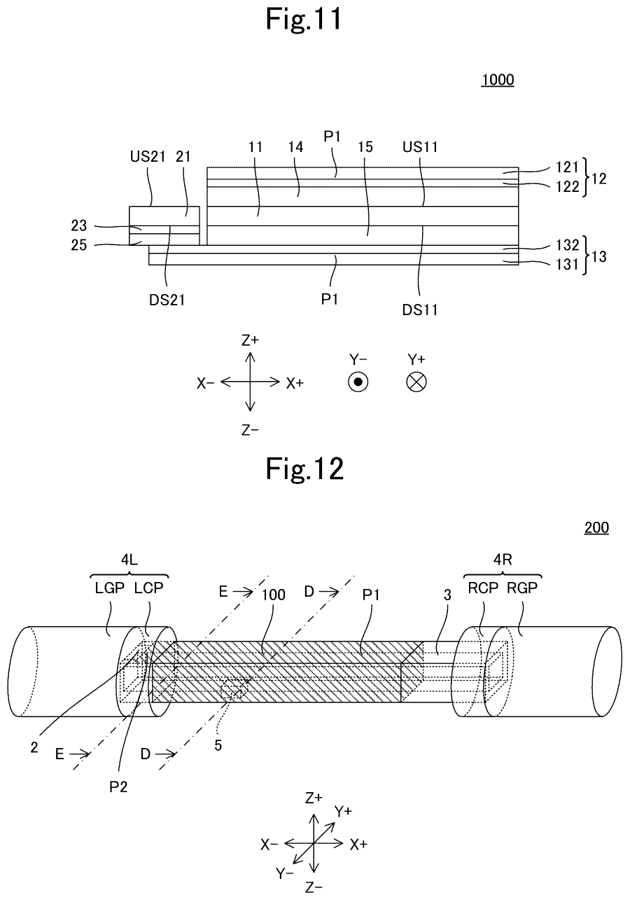

Hereinafter, a configuration of a sensor 100 according to a first embodiment of the present disclosure will be described with reference to the drawings. FIG. 1 is a plan view of the sensor 100 according to the first embodiment as viewed in a Z− direction. FIG. 2 is a sectional view of a sensor unit 1 according to the first embodiment as viewed in a Y+ direction. FIG. 3 is a plan view of a piezoelectric film 11 according to the first embodiment as viewed in the Z− direction. FIG. 4 is a plan view of the sensor unit 1 according to the first embodiment as viewed in the Z− direction. FIG. 5 is a plan view of a wiring portion 2 according to the first embodiment as viewed in the Z− direction. FIG. 6 is a sectional view of the wiring portion 2 according to the first embodiment as viewed in the Y+ direction. FIG. 7 is a sectional view taken along line A-A of the sensor 100 according to the first embodiment. FIG. 8 is a plan view of the wiring portion 2 and a second portion P2 according to the first embodiment as viewed in the Z− direction. FIG. 9 is a plan view of a sensor 1000 according to a comparative example as viewed in the Z− direction. FIG. 10 is a sectional view taken along line B-B of the sensor 1000 according to the comparative example. FIG. 11 is a sectional view taken along line C-C of the sensor 1000 according to the comparative example.

In the present description, an X-axis direction, a Y-axis direction, and a Z-axis direction are orthogonal to each other. The Z-axis direction corresponds to “first direction” of the present disclosure. The X-axis direction corresponds to “second direction” of the present disclosure. The Y-axis direction corresponds to “third direction” of the present disclosure. Further, an X+ direction is a positive direction of an X axis. An X− direction is a negative direction of the X axis. The Y+ direction is a positive direction of a Y axis. A Y− direction is a negative direction of the Y axis. A Z+ direction is a positive direction of a Z axis. The Z− direction is a negative direction of the Z axis. Note that the Z− axis direction is an example of “first direction” of the present disclosure. The X-axis direction is an example of “second direction” of the present disclosure. The Y-axis direction is an example of “third direction” of the present disclosure.

In the present description, that “an object 10 is transparent” means that the inside of the object 10 and a portion further in Y+ direction than the object 10 can be seen when the object 10 is viewed from a position further in the Y− direction than the object 10. This definition is also applied when the object 10 is viewed from a position further in a direction other than the Y− direction than the object 10. Further, this definition is also applied to an object other than the object 10 and a region.

The sensor 100 is a sensor that detects deformation of an object to be measured. As illustrated in FIG. 1, the sensor 100 includes the sensor unit 1 and the wiring portion 2. As illustrated in FIG. 2, the sensor unit 1 includes the piezoelectric film 11, a first electrode 12, a second electrode 13, a first sticky material 14, and a second sticky material 15. Further, as illustrated in FIG. 2, the sensor unit 1 has a first main surface US1 and a second main surface DS1. The first main surface US1 and the second main surface DS1 face each other in the Z-axis direction. The first main surface US1 is located further in the Z+ direction than the second main surface DS1. The first main surface US1 and the second main surface DS1 are parallel to each other.

As illustrated in FIG. 2, the piezoelectric film 11 has a third main surface US11 and a fourth main surface DS11. The third main surface US11 and the fourth main surface DS11 face each other in the Z-axis direction. The third main surface US11 corresponds to “first main surface” of the present disclosure. The fourth main surface DS11 corresponds to “second main surface” of the present disclosure. The third main surface US11 is located further in the Z+ direction than the fourth main surface DS11. The third main surface US11 and the fourth main surface DS11 are parallel to each other. Each of the third main surface US11 and the fourth main surface DS11 has a rectangular shape when viewed in the Z-axis direction. Each of the third main surface US11 and the fourth main surface DS11 has a long side extending in the X-axis direction and a short side extending in the Y-axis direction.

The piezoelectric film 11 is transparent. Further, the piezoelectric film 11 has high flexibility. Further, the piezoelectric film 11 generates a charge according to a deformation amount of the piezoelectric film 11. In the present embodiment, the piezoelectric film 11 is a PLLA film. Hereinafter, the piezoelectric film 11 will be described below in more detail.

The piezoelectric film 11 has a characteristic that polarity of a charge generated when the piezoelectric film 11 is stretched in a direction of 45 degrees with respect to the X-axis direction is opposite to polarity of a charge generated when the piezoelectric film 11 is stretched in a direction of 45 degrees with respect to the Y-axis direction. Specifically, the piezoelectric film 11 is a film formed of a chiral polymer. The chiral polymer is, for example, polylactic acid (PLA), particularly poly-L-lactic acid (PLLA). PLLA including a chiral polymer has a main chain with a helical structure. PLLA has piezoelectricity in which molecules are oriented when uniaxial stretching is performed. The piezoelectric film 11 has a piezoelectric constant of d14. As illustrated in FIG. 3, a uniaxial stretching direction (orientation direction) OD of the piezoelectric film 11 forms an angle of 0 degrees with respect to the X-axis direction. The 0 degrees include, for example, an angle including about 0 degrees±10 degrees. In a case where the piezoelectric film 11 is twisted, the piezoelectric film 11 stretches in a direction of 45 degrees with respect to the X-axis direction and the Y-axis direction to generate a charge. Magnitude of the charge depends on a twisting amount of the piezoelectric film 11.

The first electrode 12 is a ground electrode. The first electrode 12 is connected to ground potential. More specifically, as illustrated in FIG. 2, the first electrode 12 includes a first substrate 121 and a first conductive film 122. The first conductive film 122 covers an end surface in the Z− direction of the first substrate 121. The first conductive film 122 is electrically connected to ground potential.

The first electrode 12 is transparent. Further, the first electrode 12 has high flexibility. The first substrate 121 is, for example, a polyethylene terephthalate (PET) film. The first conductive film 122 is, for example, a transparent conductive film. A material of the first conductive film 122 is, for example, indium tin oxide (ITO).

The first electrode 12 is provided on the third main surface US11. More specifically, as illustrated in FIG. 2, the first electrode 12 is provided further in the Z+ direction than the first sticky material 14 provided on the third main surface US11. The first electrode 12 is fixed further in the Z+ direction than the third main surface US11 by the first sticky material 14. The first electrode 12 covers an end surface in the Z+ direction of the first sticky material 14. The first conductive film 122 is located between the first substrate 121 and the first sticky material 14. Further, the first main surface US1 of the sensor 100 is an end surface in the Z+ direction of the first electrode 12.

The first sticky material 14 is transparent. The first sticky material 14 is, for example, an optical transparent adhesive sheet. The first sticky material 14 fixes the first conductive film 122 further in the Z+ direction than the third main surface US11.

The second electrode 13 is a signal electrode. The second electrode 13 outputs a deformation detection signal SigD corresponding to deformation of the piezoelectric film 11. More specifically, as illustrated in FIG. 2, the second electrode 13 includes a second substrate 131 and a second conductive film 132. The second conductive film 132 covers an end surface in the Z+ direction of the second substrate 131. The second conductive film 132 outputs the deformation detection signal SigD corresponding to deformation of the piezoelectric film 11.

The second electrode 13 is transparent. The second electrode 13 has high flexibility. The second substrate 131 is, for example, a polyethylene terephthalate (PET) film. The second conductive film 132 is, for example, a transparent conductive film. A material of the second conductive film 132 is, for example, indium tin oxide (ITO).

The second electrode 13 is provided on the fourth main surface DS11. More specifically, as illustrated in FIG. 2, the second electrode 13 is provided further in the Z− direction than the second sticky material 15 provided on the fourth main surface DS11. The second electrode 13 is fixed further in the Z− direction than the fourth main surface DS11 by the second sticky material 15. The second electrode 13 covers an end surface in the Z− direction of the second sticky material 15. The second conductive film 132 is located between the second substrate 131 and the second sticky material 15. Further, the second main surface DS1 of the sensor 100 is an end surface in the Z− direction of the second electrode 13.

The second sticky material 15 is transparent. The second sticky material 15 is, for example, an optical transparent adhesive sheet. The second sticky material 15 fixes the second conductive film 132 further in the Z− direction than the fourth main surface DS11.

As illustrated in FIGS. 2 and 4, the first electrode 12 and the second electrode 13 overlap each other as viewed in the Z-axis direction. Further, each of the first electrode 12 and the second electrode 13 has a first portion P1 overlapping the piezoelectric film 11. Therefore, the first portion P1 is transparent. Further, the first electrode 12 and the second electrode 13 overlap each other as viewed in the Z-axis direction. Further, each of the first electrode 12 and the second electrode 13 has the second portion P2 that does not overlap the piezoelectric film 11. Therefore, the second portion P2 is transparent.

An outer edge of the first portion P1 coincides with an outer edge of the piezoelectric film 11 as viewed in the Z-axis direction. More specifically, as illustrated in FIG. 4, the first portion P1 has a rectangular shape as viewed in the Z-axis direction. Further, the first portion P1 has a long side extending in the X-axis direction and a short side extending in the Y-axis direction as viewed in the Z-axis direction. That is, as viewed in the Z-axis direction, the first portion P1 has a first side SI1 and a second side SI2 extending in the X-axis direction, and has a third side SI3 and a fourth side SI4 extending in the Y-axis direction. The first side SI1 is located further in the Y+ direction than the second side SI2. Further, the third side SI3 is located further in the Y− direction than the fourth side SI4. Therefore, the first portion P1 includes the first side SI1 that is a first end in the Y+ direction and includes the second side SI2 that is a second end in the Y− direction.

As illustrated in FIG. 4, the second portion P2 has a rectangular shape as viewed in the Z-axis direction. Further, the second portion P2 has a long side extending in the X-axis direction and a short side extending in the Y-axis direction as viewed in the Z-axis direction. That is, as viewed in the Z-axis direction, the second portion P2 has a fifth side SI5 and a sixth side SI6 extending in the X-axis direction, and has a seventh side SI7 and an eighth side SI8 extending in the Y-axis direction. Therefore, the second portion P2 includes the fifth side SI5 that is a third end in the Y+ direction and includes the sixth side SI6 that is a fourth end in the Y− direction.

As illustrated in FIG. 4, the first portion P1 and the second portion P2 are arranged in the X-axis direction. Further, a length in the Y-axis direction of the second portion P2 is shorter than a length in the Y-axis direction of the first portion P1.

As illustrated in FIG. 4, the first side SI1 of the first portion P1 is located further in the Y+ direction than the fifth side SI5 of the second portion P2 as viewed in the Z-axis direction. That is, the first end of the first portion P1 is located further in the Y+ direction than the third end of the second portion P2 as viewed in the Z-axis direction.

As illustrated in FIG. 4, the second side SI2 of the first portion P1 is located further in the Y− direction than the sixth side SI6 of the second portion P2 as viewed in the Z-axis direction. That is, the second end of the first portion P1 is located further in the Y− direction than the fourth end of the second portion P2 as viewed in the Z-axis direction.

As illustrated in FIG. 5, the wiring portion 2 includes a wiring substrate 21, a first conductor 22, a second conductor 23, a first conductive sticky material 24, and a second conductive sticky material 25. Note that the first conductive sticky material 24 is an example of “first conductive adhesive material” of the present disclosure. Further, the second conductive sticky material 25 is an example of “second conductive adhesive material” of the present disclosure.

As illustrated in FIG. 1, the wiring substrate 21 overlaps the second portion P2 when viewed in the Z-axis direction. Further, as illustrated in FIG. 5, the wiring substrate 21 has a fifth main surface US21 and a sixth main surface DS21 facing each other in the Z-axis direction. The fifth main surface US21 corresponds to “third main surface” of the present disclosure. The sixth main surface DS21 corresponds to “fourth main surface” of the present disclosure. The fifth main surface US21 is located further in the Z+ direction than the sixth main surface DS21. The fifth main surface US21 and the sixth main surface DS21 are parallel to each other. Each of the fifth main surface US21 and the sixth main surface DS21 has a rectangular shape as viewed in the Z-axis direction. Each of the fifth main surface US21 and the sixth main surface DS21 has a long side extending in the X-axis direction and a short side extending in the Y-axis direction. The wiring substrate 21 is a flexible substrate having flexibility. Further, the wiring substrate 21 is an insulator.

The first conductor 22 is a ground line. The first conductor 22 is electrically connected to ground potential. As illustrated in FIG. 6, the first conductor 22 is provided on the fifth main surface US21.

The second conductor 23 is a signal line. The second conductor 23 is electrically connected to an input terminal of an arithmetic circuit (not illustrated). As illustrated in FIG. 6, the second conductor 23 is provided on the sixth main surface DS21.

The first conductive sticky material 24 has conductivity. Further, as illustrated in FIG. 1, the first conductive sticky material 24 overlaps the second portion P2 as viewed in the Z-axis direction. Further, as illustrated in FIG. 6, the first conductive sticky material 24 is provided on an end surface in the Z+ direction of the first conductor 22. The first conductive sticky material 24 fixes the first electrode 12 further in the Z+ direction than an end surface in the Z+ direction of the first conductor 22. By the above, the first conductor 22 is electrically connected to the first electrode 12 via the first conductive sticky material 24.

The second conductive sticky material 25 has conductivity. Further, as illustrated in FIG. 1, the second conductive sticky material 25 overlaps the second portion P2 as viewed in the Z-axis direction. Further, as illustrated in FIG. 6, the second conductive sticky material 25 is provided on an end surface in the Z− direction of the second conductor 23. The second conductive sticky material 25 fixes the second electrode 13 further in the Z− direction than an end surface in the Z− direction of the second conductor 23. By the above, the second conductor 23 is electrically connected to the second electrode 13 via the second conductive sticky material 25.

As illustrated in FIG. 7, the first electrode 12, the first conductive sticky material 24, the first conductor 22, the wiring substrate 21, the second conductor 23, the second conductive sticky material 25, and the second electrode 13 are arranged in this order along the Z-axis direction in a third portion P3 overlapping the second portion P2 as viewed in the Z-axis direction. Therefore, the first electrode 12, the first conductive sticky material 24, the wiring substrate 21, the second conductive sticky material 25, and the second electrode 13 are arranged in this order along the Z-axis direction in the third portion P3 overlapping the second portion P2 as viewed in the Z-axis direction. Note that a part of the third portion P3 coincides with a part of the second portion P2. The third portion P3 corresponds to “fifth portion” of the present disclosure.

Here, as viewed in the Z-axis direction, a position in the X-axis direction where the third portion P3 exists is defined as a first position PO1 as illustrated in FIG. 8. Note that the first position PO1 may be an optional position in a position in the X-axis direction where the third portion P3 is located.

As illustrated in FIG. 8, a length L21 in the Y-axis direction of the wiring substrate 21 at the first position PO1 is longer than a length LP2 in the Y-axis direction of the second portion P2 at the first position PO1.

As illustrated in FIG. 8, a length L24 in the Y-axis direction of the first conductive sticky material 24 at the first position PO1 is shorter than the length LP2 in the Y-axis direction of the second portion P2 at the first position PO1.

As illustrated in FIG. 8, a length L25 in the Y-axis direction of the second conductive sticky material 25 at the first position PO1 is shorter than the length LP2 in the Y-axis direction of the second portion P2 at the first position PO1.

### Effect

According to the sensor 100, a connection area between an output conductor of the sensor unit 1 and an input conductor of a circuit unit as viewed in a normal direction of a main surface of the sensor unit 1 can be made small. First, the sensor 1000 according to a comparative example will be described. Note that, regarding the sensor 1000 according to the comparative example, only a portion different from that of the sensor 100 according to the first embodiment will be described, and description of a remaining portion will be omitted. In the sensor 1000 according to the comparative example, as illustrated in FIGS. 9 to 11, the first electrode 12 and the second electrode 13 do not have the second portion P2. More specifically, the first electrode 12 and the second electrode 13 do not overlap each other as viewed in the Z-axis direction at an end portion in the X− direction of the sensor unit 1 (an end in the X− direction of the sensor unit 1 and the vicinity of the end). The first electrode 12 is located in a half in the Y+ direction of the sensor unit 1 as viewed in the Z-axis direction at an end portion in the X− direction of the sensor unit 1. The second electrode 13 is located in a half in the Y− direction of the sensor unit 1 as viewed in the Z-axis direction at an end portion in the X− direction of the sensor unit 1. That is, the first electrode 12 and the second electrode 13 are arranged in the Y-axis direction as viewed in the Z-axis direction at an end portion in the X− direction of the sensor unit 1. As illustrated in FIG. 10, the first electrode 12 is electrically connected to the first conductor 22 via the first conductive sticky material 24. A connection area between the first electrode 12 and the first conductor 22 as viewed in the Z-axis direction (normal direction of the first main surface US1 of the sensor unit 1) is S1 as illustrated in FIG. 9. As illustrated in FIG. 11, the second electrode 13 is electrically connected to the second conductor 23 via the second conductive sticky material 25. A connection area between the second electrode 13 and the second conductor 23 as viewed in the Z-axis direction (normal direction of the first main surface US1 of the sensor unit 1) is S2 as illustrated in FIG. 9. Therefore, in the sensor 1000 according to the comparative example, a connection area between the first electrode 12 and the second electrode 13 of the sensor unit 1 and the first conductor 22 and the second conductor 23 of the wiring portion 2 as viewed in a normal direction of the first main surface US1 of the sensor unit 1 is S1+S2.

On the other hand, in the sensor 100 according to the first embodiment, the first electrode 12 and the second electrode 13 include the second portions P2 overlapping each other and not overlapping the piezoelectric film 11 as viewed in the Z-axis direction. Each of the first electrode 12 and the second electrode 13 is electrically connected to each of the first conductor 22 and the second conductor 23 in a region overlapping the second portion P2 as viewed in the Z-axis direction and in a region between the first electrode 12 and the second electrode 13 as viewed in the X-axis direction. By the above, a connection region between the first electrode 12 and the first conductor 22 and a connection region between the second electrode 13 and the second conductor 23 can overlap each other as viewed in the Z-axis direction. Therefore, in a case where a connection area between the first electrode 12 and the first conductor 22 viewed in the Z-axis direction (normal direction of the first main surface US1 of the sensor unit 1) is S1 as illustrated in FIG. 1, and a connection area between the second electrode 13 and the second conductor 23 viewed in the Z-axis direction (normal direction of the first main surface US1 of the sensor unit 1) is S2, in the sensor 100 according to the first embodiment, a connection area between the first electrode 12 and the second electrode 13 of the sensor unit 1 and the first conductor 22 and the second conductor 23 of the wiring portion 2 viewed in the normal direction of the first main surface US1 of the sensor unit 1 is S1 or S2. When an outer edge of the connection region between the second electrode 13 and the second conductor 23 viewed in the Z-axis direction coincides with an outer edge of the connection region between the first electrode 12 and the first conductor 22 viewed in the Z-axis direction, or is surrounded by an outer edge of the connection region between the first electrode 12 and the first conductor 22 viewed in the Z-axis direction, the sum of the connection areas between the first electrode 12 and the second electrode 13 of the sensor unit 1 and the first conductor 22 and the second conductor 23 of the wiring portion 2 viewed in the normal direction of the first main surface US1 of the sensor unit 1 is S1. Therefore, according to the sensor 100, a connection area between an output conductor of the sensor unit 1 and an input conductor of a circuit unit as viewed in a normal direction of a main surface of the sensor unit 1 can be made smaller than a connection area between an output conductor of the sensor unit 1 and an input conductor of a circuit unit as viewed in a normal direction of a main surface of the sensor unit 1 in the sensor 1000 according to the comparative example.

### Configuration of Gripping Load Detection Device 200

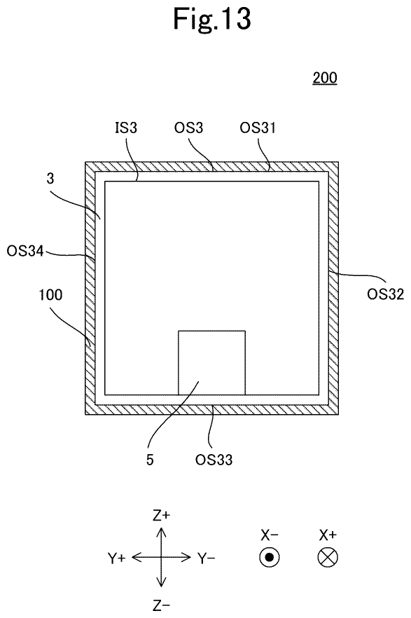

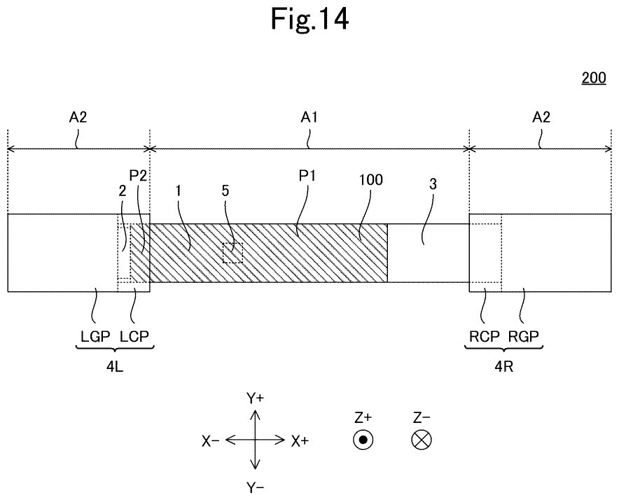

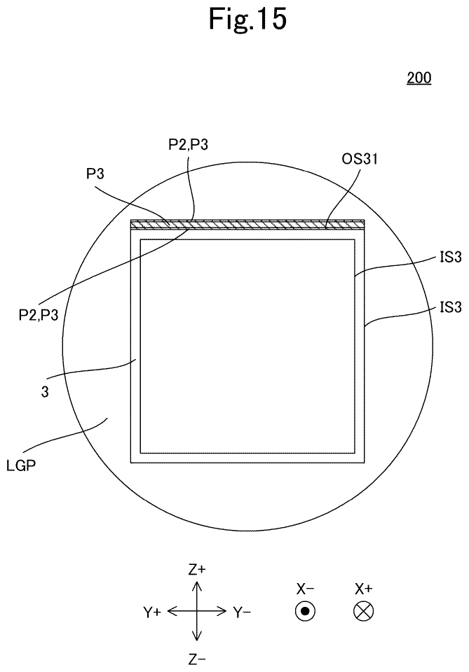

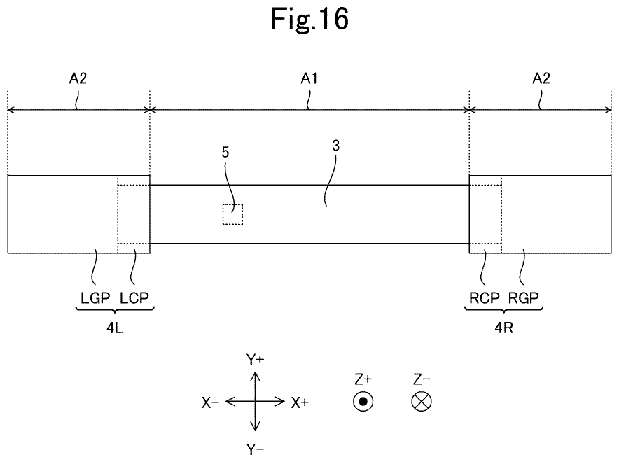

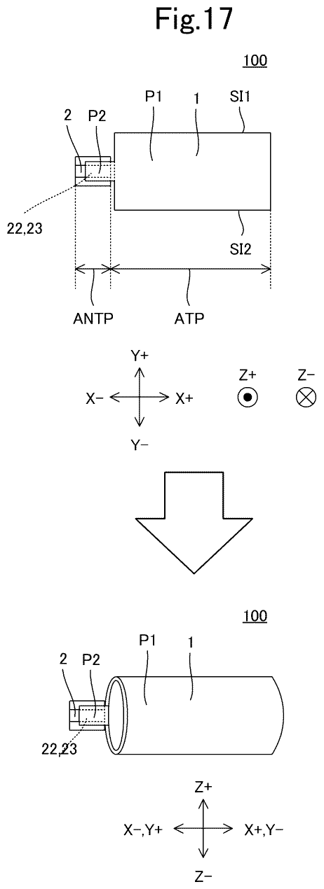

Hereinafter, a configuration of a gripping load detection device 200 according to the first embodiment of the present disclosure will be described with reference to the drawings. FIG. 12 is a perspective view of the gripping load detection device 200 according to the first embodiment. FIG. 13 is a sectional view taken along line D-D of the gripping load detection device 200 according to the first embodiment. FIG. 14 is a plan view of the gripping load detection device 200 according to the first embodiment as viewed in the Z− direction. FIG. 15 is a sectional view taken along line E-E of the gripping load detection device 200 according to the first embodiment. FIG. 16 is a plan view of a transmissive housing 3, a first grip 4L, a second grip 4R, and a light emitter 5 according to the first embodiment as viewed in the Z− direction. FIG. 17 is a diagram illustrating a transparent region ATP and a non-transparent region ANTP of the sensor unit 1 according to the first embodiment.

As illustrated in FIG. 12, the gripping load detection device 200 includes the transmissive housing 3, the first grip 4L, the second grip 4R, the sensor 100, the light emitter 5, and an arithmetic circuit (not illustrated).

The transmissive housing 3 has a tubular shape. More specifically, as illustrated in FIG. 12, the transmissive housing 3 has a quadrangular tubular shape. An axial direction of the quadrangular tubular shape is the X-axis direction.

An outer surface OS3 of the transmissive housing 3 includes a polygonal flat surface. More specifically, as illustrated in FIG. 13, the outer surface OS3 of the transmissive housing 3 includes a quadrangular flat surface. The outer surface OS3 of the transmissive housing 3 includes a first flat surface OS31, a second flat surface OS32, a third flat surface OS33, and a fourth flat surface OS34. As illustrated in FIG. 13, each of the first flat surface OS31 and the third flat surface OS33 is an end surface in the Z-axis direction in the outer surface OS3 of the transmissive housing 3. The first flat surface OS31 is an end surface in the Z+ direction. The third flat surface OS33 is an end surface in the Z− direction. Each of the second flat surface OS32 and the fourth flat surface OS34 is an end surface in the Y-axis direction in the outer surface OS3 of the transmissive housing 3. The second flat surface OS32 is an end surface in the Y+ direction. The fourth flat surface OS34 is an end surface in the Y− direction. Shapes of the first flat surface OS31, the second flat surface OS32, the third flat surface OS33, and the fourth flat surface OS34 are rectangular as viewed in normal directions of the first flat surface OS31, the second flat surface OS32, the third flat surface OS33, and the fourth flat surface OS34, respectively. A cross section of the outer surface OS3 of the transmissive housing 3 as viewed in the X-axis direction has a quadrangular shape. Each of the Z-axis direction and the Y-axis direction is one of normal directions of the outer surface OS3 of the transmissive housing 3.

As illustrated in FIG. 13, an inner surface IS3 of the transmissive housing 3 includes a quadrangular flat surface. More specifically, the inner surface IS3 of the transmissive housing 3 includes four flat surfaces. A shape of each of the four flat surfaces is rectangular when viewed in normal directions of the four flat surfaces. A cross section of the inner surface IS3 of the transmissive housing 3 as viewed in the X-axis direction has a quadrangular shape.

The transmissive housing 3 is transmissive. That is, when the transmissive housing 3 is viewed from the outside of the transmissive housing 3, a hollow portion surrounded by the inner surface IS3 of the transmissive housing 3 can be seen through. Further, light emitted from the light emitter 5 provided in the hollow portion surrounded by the inner surface IS3 of the transmissive housing 3 is emitted from the outer surface OS3 of the transmissive housing 3.

As illustrated in FIG. 12, the first grip 4L includes a first grip portion LGP and a first coupling portion LCP. The second grip 4R includes a second grip portion RGP and a second coupling portion RCP. The user grips the first grip 4L and the second grip 4R. More specifically, the user grips the first grip portion LGP and the second grip portion RGP. As illustrated in FIG. 12, the first grip 4L is attached to an end portion in the X− direction of the transmissive housing 3 by an adhesive member (not illustrated). The second grip 4R is attached to an end portion in the X+ direction of the transmissive housing 3. The second grip 4R has a structure symmetrical to the first grip 4L. For this reason, hereinafter, description will be made focusing on the first grip 4L, and description of the second grip 4R will be omitted. A material of each of the first grip 4L and the second grip 4R is, for example, resin.

The first grip 4L covers a periphery of a part of the outer surface OS3 of the transmissive housing 3. More specifically, as illustrated in FIG. 12, the first coupling portion LCP is attached to the outer surface OS3 of the transmissive housing 3 so as to cover a periphery of an end portion in the X− direction of the outer surface OS3 of the transmissive housing 3. That is, an end portion in the X− direction of the outer surface OS3 of the transmissive housing 3 is provided in a hollow portion surrounded by an inner surface of the first coupling portion LCP. By the above, the user can grip the first grip portion LGP and the second grip portion RGP and twist the transmissive housing 3.

The sensor 100 is provided on the outer surface OS3 of the transmissive housing 3. More specifically, an end surface in the Z− direction of the second electrode 13 is fixed to the outer surface OS3 of the transmissive housing 3 by a transparent adhesive member (not illustrated). The adhesive member (not illustrated) is, for example, an optical transparent adhesive sheet. The adhesive member (not illustrated) covers the entire end surface in the Z− direction of the second electrode 13. Further, the adhesive member (not illustrated) is fixed to the outer surface OS3 of the transmissive housing 3.

As illustrated in FIG. 12, the sensor 100 is provided such that a long side of the third main surface US11 of the piezoelectric film 11 extends in the X-axis direction and a short side of the third main surface US11 of the piezoelectric film 11 straddles a plurality of flat surfaces of the outer surface OS3. The short side of the third main surface US11 of the piezoelectric film 11 extends around the X-axis direction as viewed in the X-axis direction.

When the user twists the transmissive housing 3, the piezoelectric film 11 is deformed. Therefore, the sensor 100 outputs the deformation detection signal SigD corresponding to a twisting amount of the transmissive housing 3. The deformation detection signal SigD output from the sensor 100 is input to an arithmetic circuit (not illustrated).

As illustrated in FIG. 14, the first portion P1 is arranged in a first region A1 that does not overlap the first grip 4L or the second grip 4R as viewed in the Z-axis direction.

As illustrated in FIG. 14, the second portion P2 and the wiring portion 2 are arranged in a second region A2 overlapping the first grip 4L as viewed in the Z-axis direction. More specifically, the second portion P2 and the wiring portion 2 are arranged in a region overlapping first coupling portion LCP as viewed in the Z-axis direction. That is, the second portion P2 and the wiring portion 2 are provided in a hollow portion surrounded by an inner surface of first coupling portion LCP. Therefore, the second portion P2 and the wiring portion 2 are not arranged in the first region A1.

The second portion P2 is provided on one of flat surfaces of the outer surface OS3 of the transmissive housing 3. More specifically, as illustrated in FIG. 15, the second portion P2 is provided on the first flat surface OS31 of the outer surface OS3 of the transmissive housing 3. In the present embodiment, a length in the Y-axis direction of the second portion P2 is equal to a length in the Y-axis direction of the first plane OS31.

The light emitter 5 is a light emitting diode (LED). The light emitter 5 emits light by current flowing through the light emitter 5. As illustrated in FIG. 12, the light emitter 5 is provided in a hollow portion surrounded by the inner surface IS3 of the transmissive housing 3. As illustrated in FIG. 16, the light emitter 5 is arranged in the first region A1.

An arithmetic circuit (not illustrated) controls current flowing through the light emitter 5 based on the input deformation detection signal SigD. For example, a determination value is set in advance in an arithmetic circuit (not illustrated). For example, the arithmetic circuit (not illustrated) applies current to the light emitter 5 at a time when the deformation detection signal SigD is more than or equal to the determination value. That is, the light emitter 5 emits light based on the deformation detection signal SigD.

The arithmetic circuit (not illustrated) is provided in a hollow portion surrounded by the inner surface IS3 of the transmissive housing 3. The arithmetic circuit (not illustrated) is arranged in the second region A2. The arithmetic circuit (not illustrated) is not arranged in the first region A1.

### Effect

According to the sensor 100, the non-transparent region ANTP can be made small. Hereinafter, the transparent region ATP and the non-transparent region ANTP of the sensor unit 1 will be described with reference to FIG. 17. The non-transparent region ANTP of the sensor unit 1 is defined as described below. First, the sensor 100 is curved such that the first side SI1 of the first portion P1 and the second side SI2 of the first portion P1 coincide with each other as illustrated in FIG. 17. In the example of FIG. 17, the first portion P1 has a cylindrical shape. An axial direction of the cylindrical shape is the X-axis direction. Here, the first conductor 22 and the second conductor 23 are not transparent. A position in the X-axis direction where the first conductor 22 or the second conductor 23 exists is defined as a non-transparent position. The non-transparent region ANTP is a portion of the sensor 100 located at the non-transparent position. The non-transparent region ANTP is not transparent as viewed in a direction (for example, in the Z-axis direction) orthogonal to the X-axis direction. On the other hand, the first portion P1 and the second portion P2 are transparent. A position in the X-axis direction where the first portion P1 and the second portion P2 exist, the position being a position in the X-axis direction where the first conductor 22 or the second conductor 23 does not exist, is defined as a transparent position. The transparent region ATP is a portion of the sensor 100 located at the transparent position. The transparent region ATP is transparent as viewed in a direction (for example, in the Z-axis direction) orthogonal to the X-axis direction.

In view of the above, according to the sensor 100, a length in the Y-axis direction of the second portion P2 is shorter than a length in the Y-axis direction of the first portion P1. By the above, an area of the non-transparent region ANTP viewed in the Z-axis direction can be made smaller than an area of the non-transparent region ANTP viewed in the Z-axis direction in a case where a length in the Y-axis direction of the second portion P2 is not shorter than a length in the Y-axis direction of the first portion P1. As a result, according to the sensor 100, the non-transparent region ANTP can be made small.

According to the sensor 100, an area of the sensor 100 viewed in a normal direction of a main surface of the sensor unit 1 can be made small. More specifically, the first conductor 22 is provided on the fifth main surface US21 of the wiring substrate 21. The second conductor 23 is provided on the sixth main surface DS21 of the wiring substrate 21. The first electrode 12, the first conductive sticky material 24, the first conductor 22, the wiring substrate 21, the second conductor 23, the second conductive sticky material 25, and the second electrode 13 are arranged in this order along the Z-axis direction in the third portion P3 overlapping the second portion P2 as viewed in the Z-axis direction. Therefore, by arranging the first conductor 22 and the second conductor 23 so as to overlap each other as viewed in the Z-axis direction (normal direction of the first main surface US1 of the sensor unit 1), an area of the sensor 100 as viewed in the normal direction of the main surface of the sensor unit 1 can be made smaller than an area of the sensor 100 as viewed in the normal direction of the main surface of the sensor unit 1 in a case where the first conductor 22 and the second conductor 23 are arranged so as not to overlap each other as viewed in the Z-axis direction.

According to the sensor 100, it is possible to prevent the first electrode 12 and the second electrode 13 from being electrically connected to each other. More specifically, a position in the X-axis direction where the third portion P3 exists is defined as the first position PO1. A length in the Y-axis direction of the wiring substrate 21 at the first position PO1 is longer than a length in the Y-axis direction of the second portion P2 at the first position PO1. By the above, if a position in the Y-axis direction of the wiring substrate 21 deviates due to manufacturing variation, the wiring substrate 21 can be positioned between the first electrode 12 and the second electrode 13. As a result, according to the sensor 100, it is possible to prevent the first electrode 12 and the second electrode 13 from being electrically connected to each other.

According to the sensor 100, it is possible to prevent the first conductive sticky material 24 or the second conductive sticky material 25 from being electrically connected to a device outside the sensor 100. More specifically, a length in the Y-axis direction of the first conductive sticky material 24 at the first position PO1 is shorter than a length in the Y-axis direction of the second portion P2 at the first position PO1. By the above, if a position in the Y-axis direction of the first conductive sticky material 24 deviates due to manufacturing variation, the first conductive sticky material 24 can overlap the first electrode 12 and be located further in the Z− direction than the first electrode 12 as viewed in the Z-axis direction. Therefore, the first conductive sticky material 24 can be prevented from being exposed in the Z-axis direction, and the first conductive sticky material 24 can be prevented from being electrically connected to a device outside the sensor 100. Further, a length in the Y-axis direction of the second conductive sticky material 25 at the first position PO1 is shorter than a length in the Y-axis direction of the second portion P2 at the first position PO1. By the above, if a position in the Y-axis direction of the second conductive sticky material 25 deviates due to manufacturing variation, the second conductive sticky material 25 can overlap the second electrode 13 and be located further in the Z+ direction than the second electrode 13 as viewed in the Z-axis direction. Therefore, the second conductive sticky material 25 can be prevented from being exposed in the Z-axis direction, and the second conductive sticky material 25 can be prevented from being electrically connected to a device outside the sensor 100. As a result, according to the sensor 100, it is possible to prevent the first conductive sticky material 24 or the second conductive sticky material 25 from being electrically connected to a device outside the sensor 100.

According to the gripping load detection device 200, the inside of a portion of the transmissive housing 3 that can be visually recognized when the gripping load detection device 200 is viewed from the outside of the gripping load detection device 200 can be made transparent. More specifically, the sensor 100 is provided on the outer surface OS3 of the transmissive housing 3. The first portion P1 is arranged in the first region A1 that does not overlap the first grip 4L or the second grip 4R as viewed in the Z-axis direction (normal direction of the outer surface OS3 of the transmissive housing 3). The first region A1 is a portion of the transmissive housing 3 that can be visually recognized when the gripping load detection device 200 is viewed from the outside of the gripping load detection device 200. The first portion P1 is transparent. Therefore, according to the gripping load detection device 200, the inside of a portion of the transmissive housing 3 that can be visually recognized when the gripping load detection device 200 is viewed from the outside of the gripping load detection device 200 can be made transparent.

According to the gripping load detection device 200, light emitted from the light emitter 5 can be prevented from being blocked by the sensor 100. More specifically, the light emitter 5 is arranged in the first region A1 that does not overlap the first grip 4L or the second grip 4R when viewed in the Z-axis direction (the normal direction of the outer surface OS3 of the transmissive housing 3). The light emitter 5 emits light based on the deformation detection signal SigD. In the first region A1, the first portion P1 of the sensor 100 is arranged. The first portion P1 is transparent. As a result, according to the gripping load detection device 200, light emitted from the light emitter 5 can be prevented from being blocked by the sensor 100.

According to the gripping load detection device 200, the sensor 100 can be easily positioned on the outer surface OS3 of the transmissive housing 3. More specifically, the outer surface OS3 of the transmissive housing 3 includes a polygonal flat surface. The second portion P2 is provided on one of flat surfaces of the outer surface OS3. In particular, in the present embodiment, a length in the Y-axis direction of the second portion P2 is equal to a length in the Y-axis direction of the first flat surface OS31. Further, the second portion P2 is provided on the first flat surface OS31 of the outer surface OS3 of the transmissive housing 3. By the above, a position of the second portion P2 is determined. Therefore, according to the gripping load detection device 200, the sensor 100 can be easily positioned on the outer surface OS3 of the transmissive housing 3.

According to the gripping load detection device 200, a twisting amount of the transmissive housing 3 can be detected more accurately. More specifically, the first electrode 12 is a ground electrode electrically connected to ground potential. The second electrode 13 is a signal electrode that outputs the deformation detection signal SigD corresponding to a twisting amount of the transmissive housing 3. An end surface in the Z− direction of the second electrode 13 is fixed to the outer surface OS3 of the transmissive housing 3. Therefore, the second electrode 13 is located between the first electrode 12 and the outer surface OS3 of the transmissive housing 3. The first electrode 12 serves as a shield against noise entering from the outside of the gripping load detection device 200. By the above, according to the gripping load detection device 200, noise hardly enters the sensor unit 1 from the outside of the gripping load detection device 200. As a result, according to the gripping load detection device 200, a twisting amount of the transmissive housing 3 can be detected more accurately.

### First Variation

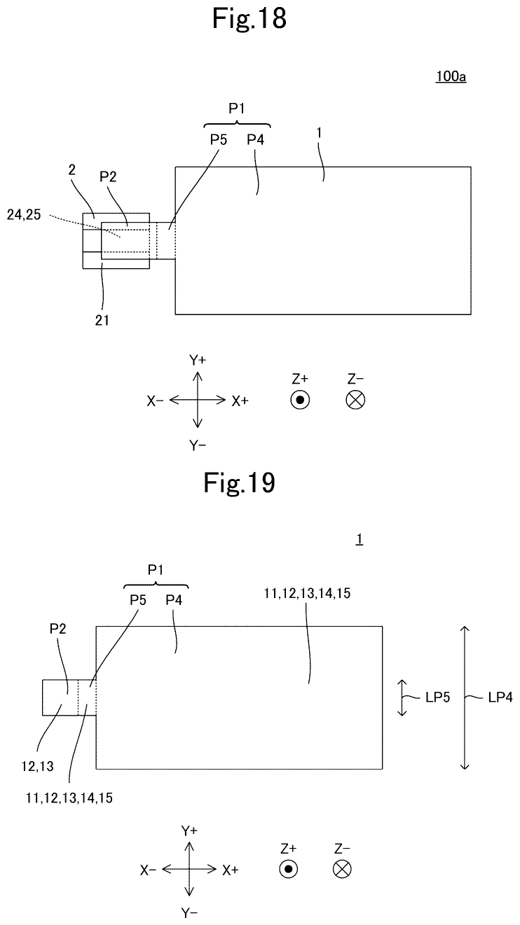

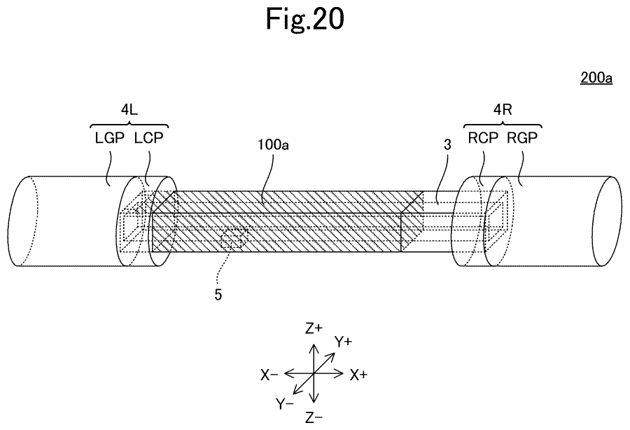

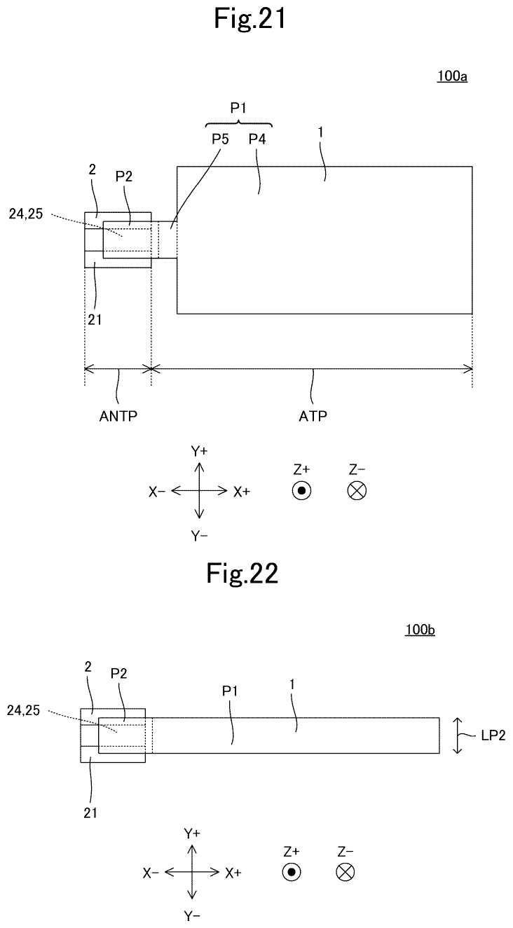

Hereinafter, a sensor 100a according to a first variation of the present disclosure will be described with reference to the drawings. FIG. 18 is a plan view of the sensor 100a according to the first variation as viewed in the Z− direction. FIG. 19 is a plan view of the sensor unit 1 according to the first variation as viewed in the Z− direction. FIG. 20 is a perspective view of a gripping load detection device 200a according to the first variation. FIG. 21 is a diagram illustrating the transparent region ATP and the non-transparent region ANTP of the sensor 100a according to the first variation. Further, regarding the sensor 100a according to the first variation, only a portion different from that of the sensor 100 according to the first embodiment will be described, and description of a remaining portion will be omitted.

As illustrated in FIG. 18, the sensor 100a is different from the sensor 100 in that the first portion P1 includes a fourth portion P4 and a fifth portion P5. The fourth portion P4 corresponds to “third portion” of the present disclosure. The fifth portion P5 corresponds to “fourth portion” of the present disclosure.

As illustrated in FIG. 19, the fourth portion P4 has a rectangular shape as viewed in the Z-axis direction.

Further, the fourth portion P4 has a long side extending in the X-axis direction and a short side extending in the Y-axis direction as viewed in the Z-axis direction.

As illustrated in FIG. 19, the fifth portion P5 has a rectangular shape as viewed in the Z-axis direction. Further, the fifth portion P5 has a long side extending in the X-axis direction and a short side extending in the Y-axis direction as viewed in the Z-axis direction.

As illustrated in FIG. 19, the fifth portion P5 is located between the second portion P2 and the fourth portion P4. Further, a length LP5 in the Y-axis direction of the fifth portion P5 is shorter than a length LP4 in the Y-axis direction of the fourth portion P4. In the present embodiment, the length LP5 in the Y-axis direction of the fifth portion P5 is equal to a length in the Y-axis direction of the second portion P2. Further, a position in the Y-axis direction of the fifth portion P5 is equal to a position in the Y-axis direction of the second portion P2.

Note that, as illustrated in FIG. 20, the sensor 100a, the transmissive housing 3, the first grip 4L, the second grip 4R, the light emitter 5, and an arithmetic circuit (not illustrated) may be modularized to form the gripping load detection device 200a.

Also in the sensor 100a as described above, the same effect as that of the sensor 100 is obtained. Further, according to the sensor 100a, the transparent region ATP can be made large with a small use amount of the piezoelectric film 11. More specifically, as illustrated in FIG. 21, the first portion P1 includes the fourth portion P4 and the fifth portion P5. The fifth portion P5 is located between the second portion P2 and the fourth portion P4. By the above, a distance between the second portion P2 and the fourth portion P4 can be made long, and the transparent region ATP can be made large. On the other hand, a length in the Y-axis direction of the fifth portion P5 is shorter than a length of the fourth portion P4. Therefore, the piezoelectric film 11 located in the fifth portion P5 can be made small. As a result, according to the sensor 100a, the transparent region ATP can be made large with a small use amount of the piezoelectric film 11.

### Second Variation

### Configuration of Sensor 100b

Hereinafter, a sensor 100b according to a second variation of the present disclosure will be described with reference to the drawings. FIG. 22 is a plan view of the sensor 100b according to the second variation as viewed in the Z− direction. Further, regarding the sensor 100b according to the second variation, only a portion different from that of the sensor 100 according to the first embodiment will be described, and description of a remaining portion will be omitted.

As illustrated in FIG. 22, the sensor 100b is different from the sensor 100 in that a length in the Y-axis direction of the second portion P2 is equal to a length in the Y-axis direction of the first portion P1.

As illustrated in FIG. 22, the sensor 100b has a

rectangular shape as viewed in the Z-axis direction. Further, the sensor 100b has a long side extending in the X-axis direction and a short side extending in the Y-axis direction as viewed in the Z-axis direction.

### Configuration of Gripping Load Detection Device 200b

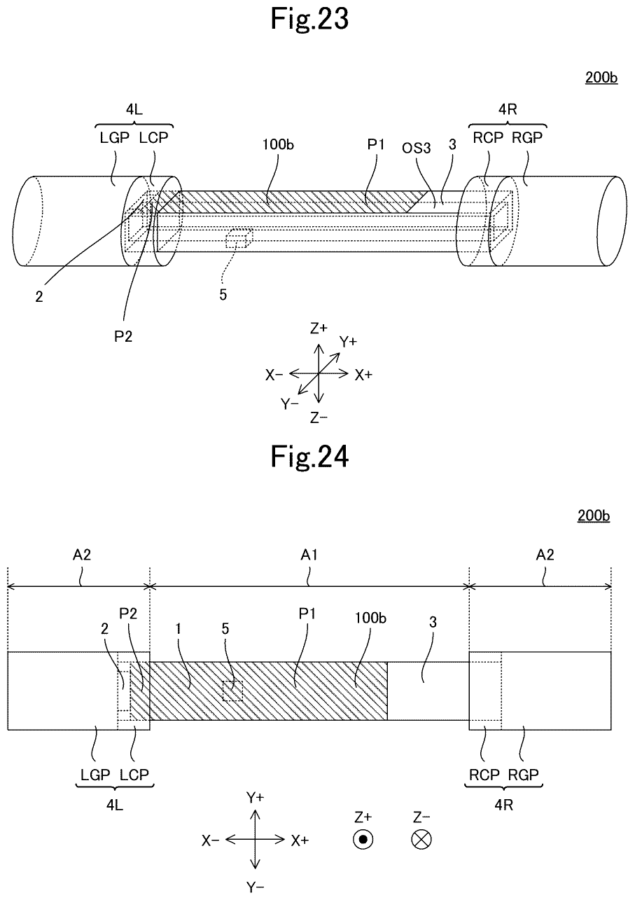

Hereinafter, a configuration of a gripping load detection device 200b according to the second variation of the present disclosure will be described with reference to the drawings. FIG. 23 is a perspective view of the gripping load detection device 200b according to the second variation. FIG. 24 is a plan view of the gripping load detection device 200b according to the second variation as viewed in the Z− direction. Further, regarding the gripping load detection device 200b according to the second variation, only a portion different from that of the gripping load detection device 200 according to the first embodiment will be described, and description of a remaining portion will be omitted.

The gripping load detection device 200b is different from the gripping load detection device 200 in that the sensor 100b is provided instead of the sensor 100.

As illustrated in FIG. 23, each of the first portion P1 and the second portion P2 is provided on the outer surface OS3 of the transmissive housing 3. As illustrated in FIG. 24, the first portion P1 is arranged in the first region A1 that does not overlap the first grip 4L or the second grip 4R as viewed in the Z-axis direction.

As illustrated in FIG. 24, the second portion P2 is arranged in the second region A2 overlapping the first grip 4L and the second grip 4R as viewed in the Z-axis direction. Further, the second portion P2 is not arranged in the first region A1.

The gripping load detection device 200b as described above also has the same effect as the gripping load detection device 200.

### Other Embodiments

The sensor according to the present disclosure is not limited to the sensor 100, 100a, or 100b, and can be changed within the scope of the gist of the present disclosure. Further, structures of the sensors 100, 100a, and 100b may be optionally combined. Further, the gripping load detection device according to the present disclosure is not limited to the gripping load detection device 200, 200a, or 200b, and can be changed within the scope of the gist of the present disclosure. Further, structures of the gripping load detection devices 200, 200a, and 200b may be optionally combined.

Note that the first sticky material 14 is not an essential component.

Note that the second sticky material 15 is not an essential component.

Note that the first main surface US1 and the second main surface DS1 do not need to be parallel to each other.

Note that the third main surface US11 and the fourth main surface DS11 do not need to be parallel to each other.

Note that each of the third main surface US11 and the fourth main surface DS11 does not need to have a rectangular shape as viewed in the Z-axis direction. Note that each of the third main surface US11 and the fourth main surface DS11 does not need to have a long side extending in the X-axis direction or a short side extending in the Y-axis direction.

Note that the piezoelectric film 11 is not limited to a PLLA film.

Note that the first electrode 12 may be a signal electrode that outputs the deformation detection signal SigD according to deformation of the piezoelectric film 11. Further, the second electrode 13 may be a ground electrode electrically connected to ground potential.

Note that the first electrode 12 does not need to have the first substrate 121.

Note that the second electrode 13 does not need to have the second substrate 131.

Note that an outer edge of the first portion P1 does not need to coincide with an outer edge of the piezoelectric film 11 as viewed in the Z-axis direction.

Note that the first portion P1 does not need to have a rectangular shape as viewed in the Z-axis direction. Further, the first portion P1 does not need to have a long side extending in the X-axis direction and does not need to have a short side extending in the Y-axis direction when viewed in the Z-axis direction.

Note that the second portion P2 does not need to have a rectangular shape as viewed in the Z-axis direction. Further, the second portion P2 does not need to have a long side extending in the X-axis direction and does not need to have a short side extending in the Y-axis direction when viewed in the Z-axis direction.

Note that, the first end of the first portion P1 does not need to be located further in the Y+ direction than the third end of the second portion P2 as viewed in the Z-axis direction.

Note that the second end of the first portion P1 does not need to be located further in the Y− direction than the fourth end of the second portion P2 as viewed in the Z-axis direction.

Note that the fifth main surface US21 and the sixth main surface DS21 do not need to be parallel to each other.

Note that each of the fifth main surface US21 and the sixth main surface DS21 does not need to have a rectangular shape as viewed in the Z-axis direction. Further, each of the fifth main surface US21 and the sixth main surface DS21 does not need to have a long side extending in the X-axis direction and a short side extending in the Y-axis direction.

Note that an arithmetic circuit is not an essential component.

Note that an adhesive member is not an essential component.

Note that shapes of the first flat surface OS31, the second flat surface OS32, the third flat surface OS33, and the fourth flat surface OS34 are not limited to a rectangular shape as viewed in normal directions of the first flat surface OS31, the second flat surface OS32, the third flat surface OS33, and the fourth flat surface OS34, respectively.

Note that a shape of each of four flat surfaces included in the outer surface OS3 of the transmissive housing 3 is not limited to a rectangular shape as viewed in a normal direction of each of the four flat surfaces.

Note that a shape of the transmissive housing 3 is not limited to a quadrangular tubular shape. The transmissive housing 3 only needs to have a polygonal tubular shape or a cylindrical shape.

Note that the first grip 4L does not need to be attached to an end portion in the X− direction of the transmissive housing 3. Further, the second grip 4R does not need to be attached to an end portion in the X+ direction of the transmissive housing 3.

Note that a length in the Y-axis direction of the second portion P2 does not need to be equal to a length in the Y-axis direction of the first flat surface OS31.

Note that the sensor 100 does not need to be provided such that a long side of the third main surface US11 of the piezoelectric film 11 extends in the X-axis direction and a short side of the third main surface US11 of the piezoelectric film 11 straddles a plurality of flat surfaces of the inner surface IS3.

Note that the light emitter 5 is not limited to a light emitting diode (LED).

Note that the fourth portion P4 does not need to have a rectangular shape as viewed in the Z-axis direction. Further, the fourth portion P4 does not need to have a long side extending in the X-axis direction and does not need to have a short side extending in the Y-axis direction as viewed in the Z-axis direction.

Note that the fifth portion P5 does not need to have a rectangular shape as viewed in the Z-axis direction. Further, the fifth portion P5 does not need to have a long side extending in the X-axis direction and does not need to have a short side extending in the Y-axis direction as viewed in the Z-axis direction.

Note that the length LP5 in the Y-axis direction of the fifth portion P5 does not need to be equal to a length in the Y-axis direction of the second portion P2. Further, a position in the Y-axis direction of the fifth portion P5 does not need to be equal to a position in the Y-axis direction of the second portion P2.

Note that, in the sensor 100b, a length in the Y-axis direction of the second portion P2 does not need to be equal to a length in the Y-axis direction of the first portion P1.

Note that, in the sensor 100b, the sensor 100 does not need to have a rectangular shape as viewed in the Z-axis direction. Further, in the sensor 100b, the sensor 100 does not need to have a long side extending in the X-axis direction and does not need to have a short side extending in the Y-axis direction as viewed in the Z-axis direction.

Note that the uniaxial stretching direction (orientation direction) OD of the piezoelectric film 11 may form an angle of 90 degrees with respect to the X-axis direction. The 90 degrees include, for example, an angle including about 90 degrees±10 degrees.

The present disclosure has a configuration below.

(1) A sensor including: a piezoelectric film having a first main surface and a second main surface facing each other in a first direction; a first electrode on the first main surface; a second electrode on the second main surface; and a wiring portion, in which the first electrode and the second electrode overlap each other as viewed in the first direction and include a first portion that overlaps the piezoelectric film and a second portion that does not overlap the piezoelectric film, the first portion and the second portion being arranged in a second direction orthogonal to the first direction, and the wiring portion includes: a wiring substrate that is an insulator, the wiring substrate overlapping the second portion as viewed in the first direction and having a third main surface and a fourth main surface facing each other in the first direction; a first conductor on the third main surface and electrically connected to the first electrode; and a second conductor on the fourth main surface and electrically connected to the second electrode.

(2) The sensor according to (1), in which a length in a third direction orthogonal to the first direction and the second direction of the second portion is shorter than a length in the third direction of the first portion.

(3) The sensor according to (1) or (2), in which the first portion is transparent.

(4) The sensor according to any of (1) to (3), in which the first portion has a rectangular shape as viewed in the first direction.

(5) The sensor according to (4), in which the first portion has a long side extending in the second direction and a short side extending in a third direction orthogonal to the first direction and the second direction as viewed in the first direction.

(6) The sensor according to any of (1) to (5), in which the second portion has a rectangular shape as viewed in the first direction.

(7) The sensor according to (6), in which the second portion has a long side extending in the second direction and a short side extending in a third direction orthogonal to the first direction and the second direction as viewed in the first direction.

(8) The sensor according to any of (1) to (7), in which the first portion includes a first end in one direction of a third direction orthogonal to the first direction and the second direction and includes a second end in an opposite direction to the one direction, the second portion includes a third end in the one direction and a fourth end in the opposite direction, the first end is located further in the one direction than the third end as viewed in the first direction, and the second end is located further in the opposite direction than the fourth end as viewed in the first direction.

(9) The sensor according to any of (1) to (8), in which the first portion includes a third portion and a fourth portion, the fourth portion is located between the second portion and the third portion, and a length in a third direction orthogonal to the first direction and the second direction of the fourth portion is shorter than a length in the third direction of the third portion.

(10) The sensor according to any of (1) to (9), in which the wiring substrate is a flexible substrate.

(11) The sensor according to any of (1) to (10), in which the wiring portion further includes: a first conductive adhesive material that overlaps the second portion when viewed in the first direction and is on an end surface in one direction in the first direction of the first conductor; and a second conductive adhesive material that overlaps the second portion when viewed in the first direction and is on an end surface in an opposite direction to the one direction of the second conductor, the first electrode, the first conductive adhesive material, the first conductor, the wiring substrate, the second conductor, the second conductive adhesive material, and the second electrode are arranged in this order along the first direction in a fifth portion overlapping the second portion as viewed in the first direction, the first conductor is electrically connected to the first electrode via the first conductive adhesive material, and the second conductor is electrically connected to the second electrode via the second conductive adhesive material.

(12) The sensor according to (11), in which a position in the second direction where the fifth portion exists as viewed in the first direction is defined as a first position, and a length in a third direction orthogonal to the first direction and the second direction of the wiring substrate at the first position is longer than a length in the third direction of the second portion at the first position.

(13) The sensor according to (11) or (12), in which a position in the second direction where the fifth portion exists as viewed in the first direction is defined as a first position, and a length in a third direction orthogonal to the first direction and the second direction of the first conductive adhesive material at the first position is shorter than a length in the third direction of the second portion at the first position, and a length in the third direction of the second conductive adhesive material at the first position is shorter than a length in the third direction of the second portion at the first position.

(14) A gripping load detection device including: the sensor according to any of (1) to (13); a transmissive housing that has a tubular shape; and a grip constructed to be gripped by a user, the grip covering a periphery of a part of an outer surface of the transmissive housing, in which the sensor is on the outer surface, the first portion is in a first region that does not overlap the grip as viewed in a normal direction of the outer surface, and the wiring portion is in a second region overlapping the grip as viewed in the normal direction, and is not in the first region.

(15) The gripping load detection device according to (14), further including: a light emitter in a hollow portion of the transmissive housing and surrounded by an inner surface of the transmissive housing, in which the sensor outputs a deformation detection signal corresponding to a twisting amount of the transmissive housing, the light emitter is in the first region, and the light emitter emits light based on the deformation detection signal.

(16) The gripping load detection device according to (14) or (15), in which the outer surface includes a polygonal flat surface, and the second portion is on the polygonal flat surface.

(17) The gripping load detection device according to any of (14) to (16), in which the first electrode is a ground electrode electrically connected to ground potential, the second electrode is a signal electrode that outputs a deformation detection signal corresponding to a twisting amount of the transmissive housing, and an end surface in the first direction of the second electrode is fixed to the outer surface.

### Description of Reference Symbols

1: Sensor unit
2: Wiring portion
3: Transmissive housing
4L: First grip
4R: Second grip
5: Light emitter
10: Object
11: Piezoelectric film
12: First electrode
13: Second electrode
14: First adhesive material
15: Second adhesive material
21: Wiring substrate
22: First conductor
23: Second conductor
24: First conductive sticky material
25: Second conductive sticky material
100, 100a, 100b: Sensor
121: First substrate
122: First conductive film
131: Second substrate
132: Second conductive film
200, 200a, 200b: Gripping load detection device
A1: First region
A2: Second region
DS11: Fourth main surface
DS21: Sixth main surface
IS3: Inner surface
OS3: Outer surface
OS31: First flat surface
OS32: Second flat surface
OS33: Third flat surface
OS34: Fourth flat surface
P1: First portion
P2: Second portion
P3: Third portion
P4: Fourth portion
P5: Fifth portion
PO1: First position
SigD: Deformation detection signal
US11: Third main surface
US21: Fifth main surface
SI1: First side
SI2: Second side
SI3: Third side
SI4: Fourth side
SI5: Fifth side
SI6: Sixth side
SI7: Seventh side
SI8: Eighth side

1. A sensor comprising:
a piezoelectric film having a first main surface and a second main surface facing each other in a first direction;
a first electrode on the first main surface;
a second electrode on the second main surface; and
a wiring portion,
wherein the first electrode and the second electrode overlap each other as viewed in the first direction and include a first portion that overlaps the piezoelectric film and a second portion that does not overlap the piezoelectric film, the first portion and the second portion being arranged in a second direction orthogonal to the first direction, and
the wiring portion includes:
a wiring substrate that is an insulator, the wiring substrate overlapping the second portion as viewed in the first direction and having a third main surface and a fourth main surface facing each other in the first direction;
a first conductor on the third main surface and electrically connected to the first electrode; and
a second conductor on the fourth main surface and electrically connected to the second electrode.

2. The sensor according to claim 1, wherein a length in a third direction orthogonal to the first direction and the second direction of the second portion is shorter than a length in the third direction of the first portion.

3. The sensor according to claim 1, wherein the first portion is transparent.

4. The sensor according to claim 1, wherein the first portion has a rectangular shape as viewed in the first direction.

5. The sensor according to claim 4, wherein the first portion has a long side extending in the second direction and a short side extending in a third direction orthogonal to the first direction and the second direction as viewed in the first direction.

6. The sensor according to claim 1, wherein the second portion has a rectangular shape as viewed in the first direction.

7. The sensor according to claim 6, wherein the second portion has a long side extending in the second direction and a short side extending in a third direction orthogonal to the first direction and the second direction as viewed in the first direction.

8. The sensor according to claim 1, wherein
the first portion includes a first end in one direction of a third direction orthogonal to the first direction and the second direction and includes a second end in an opposite direction to the one direction,
the second portion includes a third end in the one direction and a fourth end in the opposite direction,
the first end is located further in the one direction than the third end as viewed in the first direction, and
the second end is located further in the opposite direction than the fourth end as viewed in the first direction.

9. The sensor according to claim 1, wherein
the first portion includes a third portion and a fourth portion,
the fourth portion is located between the second portion and the third portion, and
a length in a third direction orthogonal to the first direction and the second direction of the fourth portion is shorter than a length in the third direction of the third portion.

10. The sensor according to claim 1, wherein the wiring substrate is a flexible substrate.

11. The sensor according to claim 1, wherein the wiring portion further includes:
a first conductive adhesive material that overlaps the second portion as viewed in the first direction and is on an end surface in one direction in the first direction of the first conductor; and
a second conductive adhesive material that overlaps the second portion as viewed in the first direction and is on an end surface in an opposite direction to the one direction of the second conductor,
the first electrode, the first conductive adhesive material, the first conductor, the wiring substrate, the second conductor, the second conductive adhesive material, and the second electrode are arranged in this order along the first direction in a fifth portion overlapping the second portion as viewed in the first direction,
the first conductor is electrically connected to the first electrode via the first conductive adhesive material, and
the second conductor is electrically connected to the second electrode via the second conductive adhesive material.

12. The sensor according to claim 11, wherein
a position in the second direction where the fifth portion exists as viewed in the first direction is defined as a first position, and
a length in a third direction orthogonal to the first direction and the second direction of the wiring substrate at the first position is longer than a length in the third direction of the second portion at the first position.

13. The sensor according to claim 12, wherein
a length in the third direction of the first conductive adhesive material at the first position is shorter than a length in the third direction of the second portion at the first position, and
a length in the third direction of the second conductive adhesive material at the first position is shorter than a length in the third direction of the second portion at the first position.

14. The sensor according to claim 11, wherein
a position in the second direction where the fifth portion exists as viewed in the first direction is defined as a first position,
a length in a third direction orthogonal to the first direction and the second direction of the first conductive adhesive material at the first position is shorter than a length in the third direction of the second portion at the first position, and
a length in the third direction of the second conductive adhesive material at the first position is shorter than a length in the third direction of the second portion at the first position.

15. A gripping load detection device comprising:
the sensor according to claim 1;
a transmissive housing that has a tubular shape; and
a grip constructed to be gripped by a user, the grip covering a periphery of a part of an outer surface of the transmissive housing,
wherein the sensor is on the outer surface,
the first portion is in a first region that does not overlap the grip as viewed in a normal direction of the outer surface, and
the wiring portion is in a second region overlapping the grip as viewed in the normal direction, and is not in the first region.

16. The gripping load detection device according to claim 15, further comprising:
a light emitter in a hollow portion of the transmissive housing and surrounded by an inner surface of the transmissive housing
wherein the sensor outputs a deformation detection signal corresponding to a twisting amount of the transmissive housing,
the light emitter is in the first region, and
the light emitter emits light based on the deformation detection signal.

17. The gripping load detection device according to claim 15, wherein
the outer surface includes a polygonal flat surface, and
the second portion is on the polygonal flat surface.

18. The gripping load detection device according to claim 15, wherein
the first electrode is a ground electrode electrically connected to ground potential,
the second electrode is a signal electrode that outputs a deformation detection signal corresponding to a twisting amount of the transmissive housing, and
an end surface in the first direction of the second electrode is fixed to the outer surface.
